(19) United States
(12) Patent Application Publication
(10) Pub. No.: US 2025/0151208 A1
(43) Pub. Date: May 8, 2025

(54) SYSTEMS AND METHODS FOR OPTIMIZING METAL WEIGHT OF CONDUCTIVE LAYERS OF CIRCUIT BOARD

(71) Applicant: Dell Products L.P., Round Rock, TX (US)

(72) Inventors: Steven R. ETHRIDGE, Austin, TX (US); Sandor T. FARKAS, Round Rock, TX (US); Bhyrav M. MUTNURY, Austin, TX (US)

(73) Assignee: Dell Products L.P., Round Rock, TX (US)

(21) Appl. No.: 18/502,990

(22) Filed: Nov. 6, 2023

(51) Int. Cl. H05K 3/46; H05K 1/02; H05K 3/24

(52) U.S. Cl. CPC H05K 3/4655; H05K 1/0298; H05K 3/243; H05K 2201/0355

(57) ABSTRACT

A method for forming a circuit board may include, in a conductive layer of the circuit board, applying a layer of metal foil to a first insulating layer of the circuit board, selectively plating the layer of metal with additional metal, removing portions of the layer of metal foil such that the selectively plating and removing steps create a plurality of conductive traces including a first conductive trace and a second conductive trace within a conductive layer of the circuit board, wherein a first thickness of the first conductive trace from a surface of the first insulating layer is different than a second thickness of the second conductive trace from the surface, and laminating a second insulating layer over the conductive layer.

### TECHNICAL FIELD

The present disclosure relates in general to information handling systems, and more particularly to patterning techniques to minimize metal weight used in inner conductive layers of a circuit board.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems may often use one or more circuit boards. A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

Circuit boards with many conductive layers are often thick and have high density of conductive routing. Sometimes, it may be desirable to use different metal thickness in the same conductive layer to optimize routing density between high-speed and low-speed signals and in patterning power and ground layers. For example, in a signal layer, it may be desirable to have thicker metal traces for better signal integrity of critical signals and for better power delivery, while maintaining the rest of the layer to have thinner traces for high routing density.

While techniques currently exist to generate traces of varying thickness in a conductive layer, such approaches may have disadvantages. For example, one approach may be to provide a thick metal (e.g., copper) foil for a layer and then selectively etch the layer to create desired varying thicknesses of traces throughout the layer. However, the use of thicker metal foils may be expensive and controlling metal thickness through a controlled chemical etching process may be difficult and lead to non-uniformity among the metal layer.

### SUMMARY

In accordance with the teachings of the present disclosure, the disadvantages and problems associated with traditional approaches to forming a metal layer having traces with varying thicknesses may be substantially reduced or eliminated.

In accordance with embodiments of the present disclosure, a method for forming a circuit board may include, in a conductive layer of the circuit board, applying a layer of metal foil to a first insulating layer of the circuit board, selectively plating the layer of metal with additional metal, removing portions of the layer of metal foil such that the selectively plating and removing steps create a plurality of conductive traces including a first conductive trace and a second conductive trace within a conductive layer of the circuit board, wherein a first thickness of the first conductive trace from a surface of the first insulating layer is different than a second thickness of the second conductive trace from the surface, and laminating a second insulating layer over the conductive layer.

In accordance with these and other embodiments of the present disclosure, a circuit board may include a first insulating layer, a conductive layer comprising a plurality of conductive traces including a first conductive trace and a second conductive trace, wherein the first conductive trace comprises metal foil applied to the first insulating layer and additional metal plated upon the metal foil of the first conductive trace, and further wherein a first thickness of the first conductive trace from a surface of the first insulating layer is different than a second thickness of the second conductive trace from the surface, and a second insulating layer is laminated over the conductive layer.

In accordance with these and other embodiments of the present disclosure, an information handling system may include a processor and a circuit board communicatively coupled to the processor and comprising a first insulating layer and a conductive layer comprising a plurality of conductive traces including a first conductive trace and a second conductive trace, wherein the first conductive trace comprises metal foil applied to the first insulating layer and additional metal plated upon the metal foil of the first conductive trace, and further wherein a first thickness of the first conductive trace from a surface of the first insulating layer is different than a second thickness of the second conductive trace from the surface and a second insulating layer laminated over the conductive layer.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example information handling system, in accordance with embodiments of the present disclosure;

FIG. 2 illustrates a flow chart of an example method for creating traces of varying thicknesses in a conductive layer of a circuit board, in accordance with embodiments of the present disclosure; and

FIGS. 3A-3F illustrate perspective views of selected portions of a circuit board depicting various steps of an example method for creating traces of varying thicknesses in a conductive layer of a circuit board, in accordance with embodiments of the present disclosure.

### DETAILED DESCRIPTION

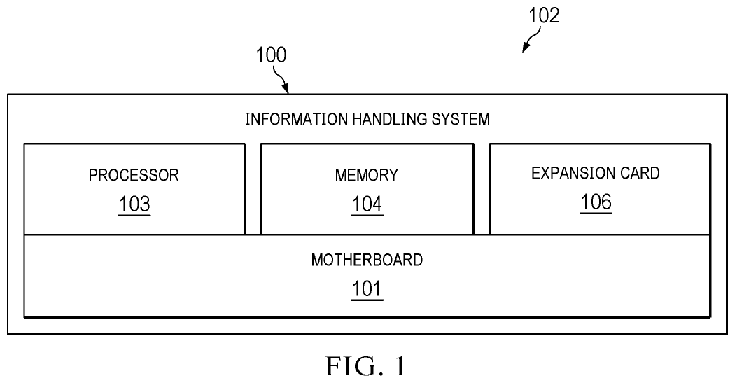

Preferred embodiments and their advantages are best understood by reference to FIGS. 1 through 3F, wherein like numbers are used to indicate like and corresponding parts.

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

For the purposes of this disclosure, information handling resources may broadly refer to any component system, device or apparatus of an information handling system, including without limitation processors, service processors, basic input/output systems, buses, memories, I/O devices and/or interfaces, storage resources, network interfaces, motherboards, air movers, sensors, power supplies, and/or any other components and/or elements of an information handling system.

For the purposes of this disclosure, circuit boards may broadly refer to printed circuit boards (PCBs), printed wiring boards (PWBs), printed wiring assemblies (PWAs), etched wiring boards, and/or any other board or similar physical structure operable to mechanically support and electrically couple electronic components (e.g., packaged integrated circuits, slot connectors, etc.). A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

FIG. 1 illustrates a block diagram of selected components of an example information handling system 102. In some embodiments, information handling system 102 may comprise a server. In other embodiments, information handling system 102 may comprise networking equipment for facilitating communication over a communication network. In yet other embodiments, information handling system 102 may comprise a personal computer, such as a laptop, notebook, or desktop computer.

As shown in FIG. 1, information handling system 102 may include a chassis 100 that houses a motherboard 101, a processor 103 coupled to motherboard 101, a memory 104 coupled to motherboard 101, and an expansion card 106 mechanically and electrically coupled to motherboard 101.

Chassis 100 may include any suitable housing or enclosure configured to house the various components of information handling system 102, and may be constructed from metal, plastic, and/or any other suitable material.

Motherboard 101 may comprise a circuit board configured to provide structural support for one or more information handling resources of information handling system 102 and/or electrically couple one or more of such information handling resources to each other and/or to other electric or electronic components external to information handling system 102.

Processor 103 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in a storage resource, memory system 104, and/or another component of information handling system 102.

Memory 104 may be communicatively coupled to processor 103 and may comprise any system, device, or apparatus operable to retain program instructions or data for a period of time (e.g., computer-readable media). Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off. In particular embodiments, memory 104 may comprise dynamic random access memory (DRAM).

Expansion card 106 may comprise any suitable circuit board. In some embodiments, expansion card 106 may comprise a riser card. Although not explicitly shown in FIG. 1, motherboard 101 and expansion card 106 may each have respective connectors for electrically and manually coupling expansion card 106 to motherboard 101. For example, in some embodiments, expansion card 106 may have an edge connector formed on an edge thereof configured to couple to a corresponding receptacle connector either surface-mounted to motherboard 101 or edge-mounted (e.g., a straddle-mount connector) to motherboard 101.

In addition to motherboard 101, processor 103, memory 104, and expansion card 106, information handling system 102 may include one or more other information handling resources.

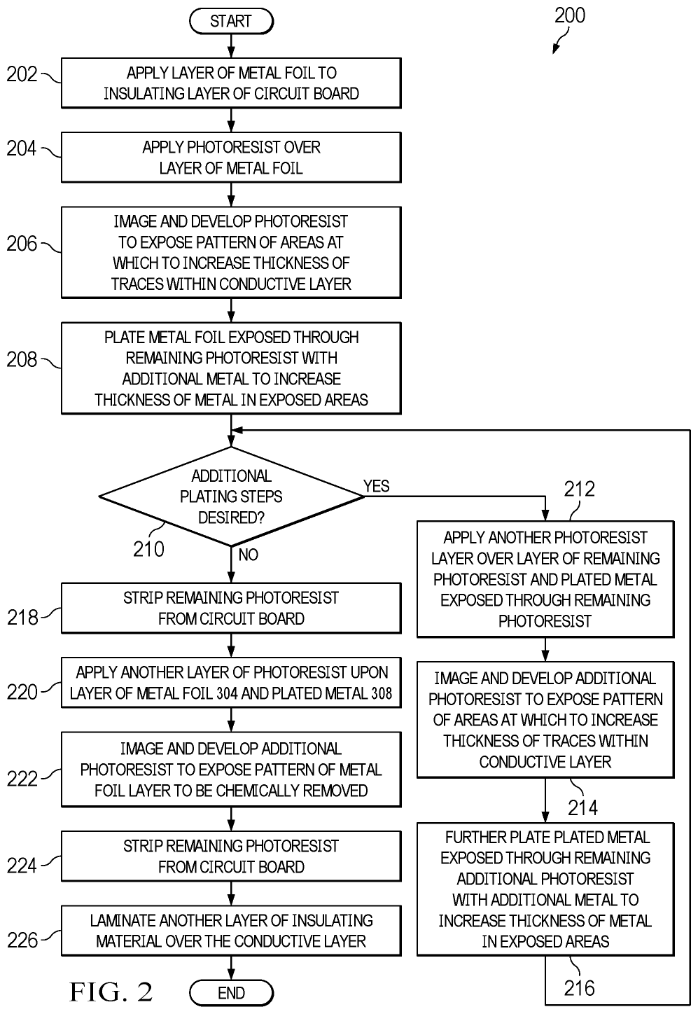

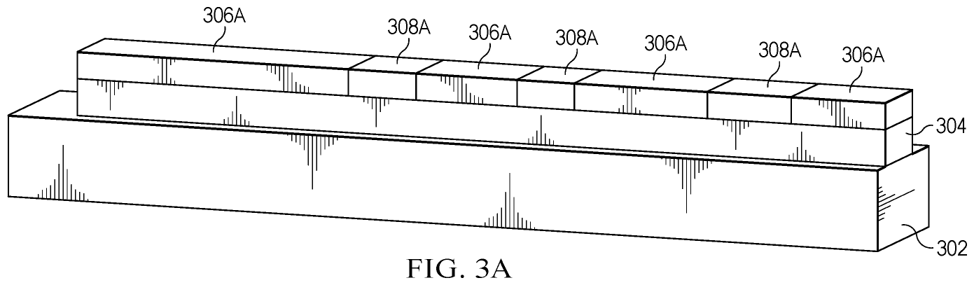

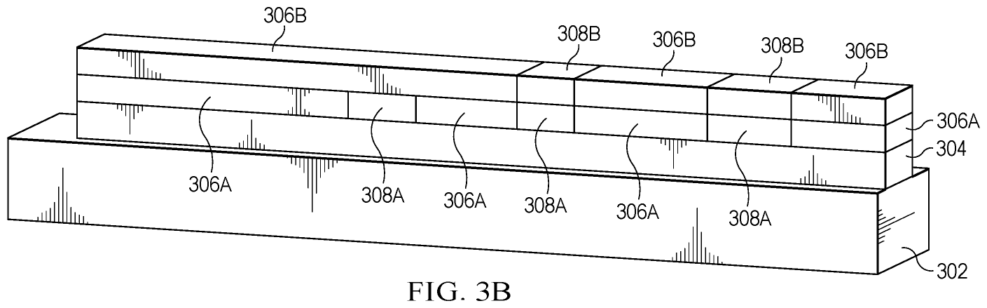

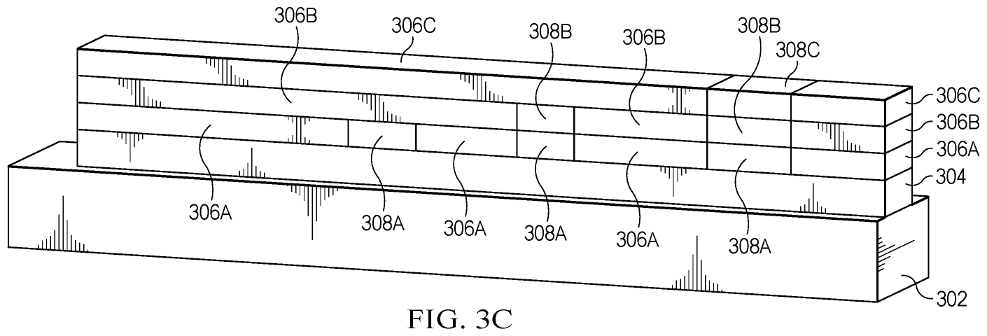

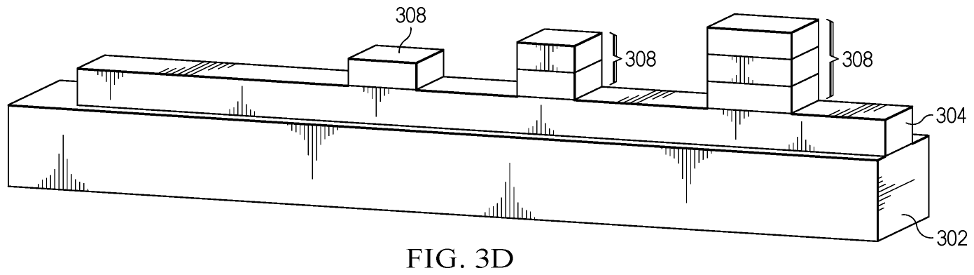

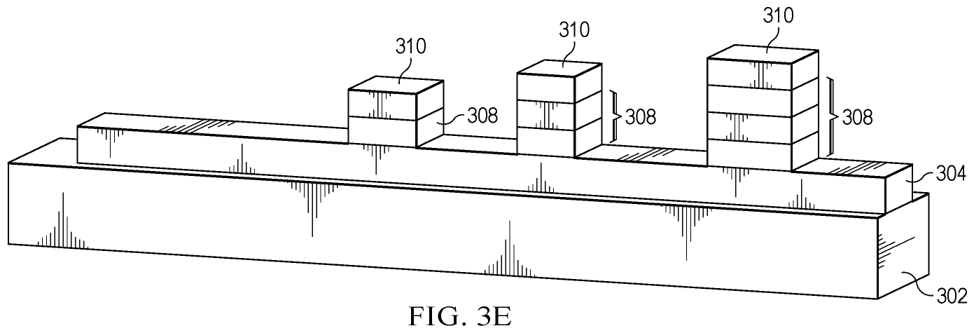

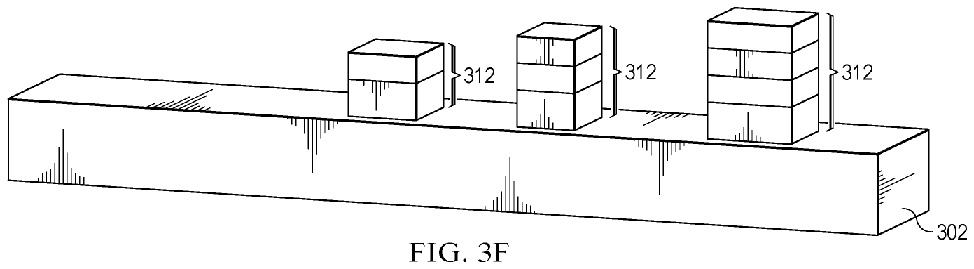

In some embodiments, all or portions of motherboard 101, memory 104, expansion card 106, and/or other information handling resources of information handling system 102 may be made using the process described in reference to FIGS. 2 and 3 below.

FIG. 2 illustrates a flow chart of an example method 200 for creating traces of varying thicknesses in a conductive layer of a circuit board using a photolithographic process, in accordance with embodiments of the present disclosure. According to some embodiments, method 200 may begin at step 202. As noted above, teachings of the present disclosure may be implemented in a variety of configurations of an information handling system 102, an expansion card 106, or its various components. As such, the preferred initialization point for method 200 and the order of the steps comprising method 200 may depend on the implementation chosen.

At step 202, a layer of metal (e.g., copper) foil may be applied upon an insulating layer of a circuit board. At step 204, a photoresist may be applied over the layer of metal foil. At step 206, the photoresist layer may be imaged and developed to expose a pattern of areas in the photoresist at which to increase thickness of traces within the conductive layer. At step 208, the metal foil exposed through the remaining photoresist may be plated with additional metal (e.g., copper) to increase thickness of metal in the exposed areas.

Turning briefly away from FIG. 2, FIG. 3A illustrates a perspective view of selected portions of a circuit board depicting an insulating layer 302 of a circuit board, a layer of metal foil 304 applied to insulating layer 302 (e.g., as in step 202 above), remaining portions of a photoresist 306A (e.g., applied in step 204 above, and imaged and developed in step 206 above), and plated metal 308A plated onto the layer of metal foil 304 in areas exposed by photoresist 306A (e.g., as in step 208 above).

Turning back to FIG. 2, at step 210, if additional plating steps are desired to increase trace thicknesses, method 200 may proceed to step 212. Otherwise, if no additional plating steps are desired, method 200 may proceed to step 218.

At step 212, another photoresist may be applied over the layer of remaining photoresist and plated metal exposed through the remaining photoresist. At step 214, the additional photoresist layer may be imaged and developed to expose a pattern of areas in the photoresist at which to further increase thickness of traces within the conductive layer. At step 216, the plated metal exposed through the remaining additional photoresist may be further plated with additional metal (e.g., copper) to increase thickness of metal in the exposed areas. After completion of step 216, method 200 may proceed again to step 210.

Turning again briefly away from FIG. 2, FIG. 3B illustrates a perspective view of selected portions of a circuit board depicting, in addition to that depicted in FIG. 3A above, remaining portions of a photoresist 306B (e.g., applied in step 212 above, and imaged and developed in step 214 above), and plated metal 308B plated onto plated metal 308A in areas exposed by photoresist 306B (e.g., as in step 214 above).

The steps 212-216 of method 200 may be repeated as desired to add additional thickness to one or more traces. For example, FIG. 3C illustrates a perspective view of selected portions of a circuit board depicting, in addition to that depicted in FIG. 3B above, results of a third plating step including remaining portions of a photoresist 306C (e.g., applied in a second execution of step 212 above, and imaged and developed in a second execution of step 214 above), and plated metal 308C plated onto plated metal 308B in areas exposed by photoresist 306C (e.g., in a second execution of step 214 above).

Turning again to FIG. 2, at step 218, the remaining photoresist may be stripped from the circuit board. As shown in FIG. 3D, execution of step 218 may result in plated metal 308 of various thicknesses formed upon the layer of metal foil 304.

At step 220, another layer of photoresist may be applied upon the layer of metal foil 304 and plated metal 308. At step 222, such photoresist layer may be imaged and developed to expose a pattern of the metal foil layer to be chemically removed. As shown in FIG. 3E, method 200 as executed through step 222 may result in undeveloped photoresist 310 upon plated metal 308.

At step 224, the remaining photoresist may be stripped from the circuit board. As shown in FIG. 3F, execution of step 224 may result in traces 312 of various thicknesses formed within a conductive layer of the circuit board, each trace comprising metal foil with metal plated thereupon.

At step 226, another layer of insulating material may be laminated over the conductive layer to electrically isolate the conductive layer from other conductive layers in the circuit board. After step 226, method 200 may end, although method 200 may be repeated for one or more other conductive layers of the circuit board.

Although FIG. 2 discloses a particular number of steps to be taken with respect to method 200, method 200 may be executed with greater or fewer steps than those depicted in FIG. 2. In addition, although FIG. 2 discloses a certain order of steps to be taken with respect to method 200, the steps comprising method 200 may be completed in any suitable order.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112 (f) unless the words “means for” or “step for” are explicitly used in the particular claim.

What is claimed is:

1. A method for forming a circuit board, comprising, in a conductive layer of the circuit board:
applying a layer of metal foil to a first insulating layer of the circuit board;
selectively plating the layer of metal with additional metal;
removing portions of the layer of metal foil such that the selectively plating and removing steps create a plurality of conductive traces including a first conductive trace and a second conductive trace within a conductive layer of the circuit board, wherein a first thickness of the first conductive trace from a surface of the first insulating layer is different than a second thickness of the second conductive trace from the surface; and
laminating a second insulating layer over the conductive layer.

2. The method of claim 1, wherein the layer of metal foil is formed of copper.

3. The method of claim 1, wherein the additional metal is copper.

4. The method of claim 1, wherein selectively plating the layer of metal with additional metal comprises plating the additional metal to varying thicknesses throughout the layer of metal.

5. The method of claim 1, wherein the selectively plating and removing steps are performed using a photolithographic process.

6. A circuit board, comprising:
a first insulating layer;
a conductive layer comprising a plurality of conductive traces including a first conductive trace and a second conductive trace, wherein:
the first conductive trace comprises:
metal foil applied to the first insulating layer; and
additional metal plated upon the metal foil of the first conductive trace; and
a first thickness of the first conductive trace from a surface of the first insulating layer is different than a second thickness of the second conductive trace from the surface; and
a second insulating layer laminated over the conductive layer.

7. The circuit board of claim 6, wherein the layer of metal foil is formed of copper.

8. The circuit board of claim 6, wherein the additional metal is copper.

9. The circuit board of claim 6, wherein selectively plating the layer of metal with additional metal comprises plating the additional metal to varying thicknesses throughout the layer of metal.

10. The circuit board of claim 6, wherein the plurality of conductive traces are formed using a photolithographic process.

11. An information handling system, comprising:
a processor; and
a circuit board communicatively coupled to the processor and comprising:
a first insulating layer;
a conductive layer comprising a plurality of conductive traces including a first conductive trace and a second conductive trace, wherein:
the first conductive trace comprises:
metal foil applied to the first insulating layer; and
additional metal plated upon the metal foil of the first conductive trace; and
a first thickness of the first conductive trace from a surface of the first insulating layer is different than a second thickness of the second conductive trace from the surface; and
a second insulating layer laminated over the conductive layer.

12. The information handling system of claim 11, wherein the layer of metal foil is formed of copper.

13. The information handling system of claim 11, wherein the additional metal is copper.

14. The information handling system of claim 11, wherein selectively plating the layer of metal with additional metal comprises plating the additional metal to varying thicknesses throughout the layer of metal.

15. The information handling system of claim 11, wherein the plurality of conductive traces are formed using a photolithographic process.
